(19) United States
(12) Patent Application Publication
(10) Pub. No.: US 2019/0393053 A1
(43) Pub. Date: Dec. 26, 2019

(54) ETCHING APPARATUS

(71) Applicant: Applied Materials, Inc., Santa Clara, CA (US)

(72) Inventors: Yang YANG, San Diego, CA (US); Kartik RAMASWAMY, San Jose, CA (US); Kenneth S. COLLINS, San Jose, CA (US); Steven LANE, Porterville, CA (US); Gonzalo MONROY, San Francisco, CA (US); Lucy Zhiping CHEN, Santa Clara, CA (US); Yue GUO, Redwood City, CA (US)

(21) Appl. No.: 16/441,579

(22) Filed: Jun. 14, 2019

Related U.S. Application Data
(60) Provisional application No. 62/687,760, filed on Jun. 20, 2018.

(51) Int. Cl. H01L 21/67; H01L 21/311; C23C 16/517; C23C 16/02

(52) U.S. Cl. CPC H01L 21/67069; H01L 21/31116; H01J 2237/3151; C23C 16/0245; H01J 2237/3137; C23C 16/517

(57) ABSTRACT

Embodiments described herein relate to apparatus for performing electron beam reactive plasma etching (EBRPE). In one embodiment, an apparatus for performing EBRPE processes includes an electrode formed from a material having a high secondary electron emission coefficient. In another embodiment, an electrode is movably disposed within a process volume of a process chamber and capable of being positioned at a non-parallel angle relative to a pedestal opposing the electrode. In another embodiment, a pedestal is movably disposed with a process volume of a process chamber and capable of being positioned at a non-parallel angle relative to an electrode opposing the pedestal. Electrons emitted from the electrode are accelerated toward a substrate disposed on the pedestal to induce etching of the substrate.

### CROSS-REFERENCE TO RELATED APPLICATIONS

This application claims priority to U.S. Provisional Patent Application No. 62/687,760, filed Jun. 20, 2018, the entirety of which is herein incorporated by reference.

### BACKGROUND

### Field

Embodiments of the present disclosure generally relate to apparatus for etching a substrate. More specifically, embodiments described herein relate to methods and apparatus for electron beam reactive plasma etching.

### Description of the Related Art

In the semiconductor manufacturing industry, various technological advances have enabled production of increasingly complex devices at advanced technology nodes. For example, device feature sizes have been reduced to the nanometer scale and the geometric complexity of such features has grown increasingly complex. Etching processes used to fabricate such devices are often a limiting factor in further development of advanced devices.

Reactive ion etching (RIE) is a conventional etching technique which utilizes ion bombardment to induce etching reactions on a substrate. With RIE it is possible to generate anisotropic etching profiles, however, certain ion energy thresholds are often necessary to induce desired etching reactions and to control the etching profile. The ion energy thresholds often reduce etch selectivity and may damage the structure being etched.

Electron beams are another technology commonly used in the semiconductor manufacturing industry. Electrons beams, when utilized with suitable etching gas chemistries, can induce etching on a substrate. However, conventional electron beam etching apparatus typically emit an electron beam with a cross section on the micrometer scale which is not practical for forming nanometer scale advanced devices. In addition, conventional electron beam technology is typically unsuitable for fabrication of advanced optical devices and the like which employ complex topographical features.

Thus, what is needed in the art are improved etching apparatus.

### SUMMARY

In one embodiment, a substrate processing apparatus is provided. The apparatus includes a chamber body defining a volume, a pedestal disposed in the volume, and a ceiling coupled to the chamber body opposite the pedestal. An electrode is disposed in the volume between the pedestal and the ceiling. At least one of the electrode or the pedestal is movable to orient a surface of the electrode facing a surface of the pedestal in a non-parallel orientation.

In another embodiment, a substrate processing apparatus is provided. The apparatus includes a chamber body defining a volume, a ceiling coupled to the chamber body, an electrode coupled to the ceiling, and a pedestal disposed in the volume and having a surface facing a surface of the electrode. An actuator is coupled to the pedestal and configured to position a surface of the pedestal facing the surface of the electrode in a non-parallel orientation relative to the surface of the electrode.

In yet another embodiment, a substrate processing apparatus is provided. The apparatus includes a chamber body defining a volume, an electrode for performing electron beam reactive plasma etching disposed in the volume, and a pedestal coupled to a support shaft, the pedestal being disposed in the volume opposite the electrode. A conductive mesh is disposed in the pedestal, a plurality of shafts is coupled to either the electrode or the pedestal, and one or more ball screw actuators are coupled to the shafts. A first gas injector is coupled to the chamber body adjacent to the electrode and a second gas injector is coupled to the chamber body adjacent to the pedestal.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 schematically illustrates an electron beam reactive plasma etching (EBRPE) apparatus according to an embodiment described herein.

FIG. 2 schematically illustrates an EBRPE apparatus according to another embodiment described herein.

FIG. 3 illustrates an actuator assembly of an EBRPE apparatus according to an embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein relate to apparatus for performing electron beam reactive plasma etching (EBRPE). In one embodiment, an apparatus for performing EBRPE processes includes an electrode formed from a material having a high secondary electron emission coefficient. In another embodiment, an electrode is movably disposed within a process volume of a process chamber and capable of being positioned at a non-parallel angle relative to a major axis of a pedestal opposing the electrode. In another embodiment, a pedestal is movably disposed with a process volume of a process chamber and capable of being positioned at a non-parallel angle relative to a major axis of an electrode opposing the pedestal. Electrons emitted from the electrode are accelerated toward a substrate disposed on the pedestal to induce etching of the substrate.

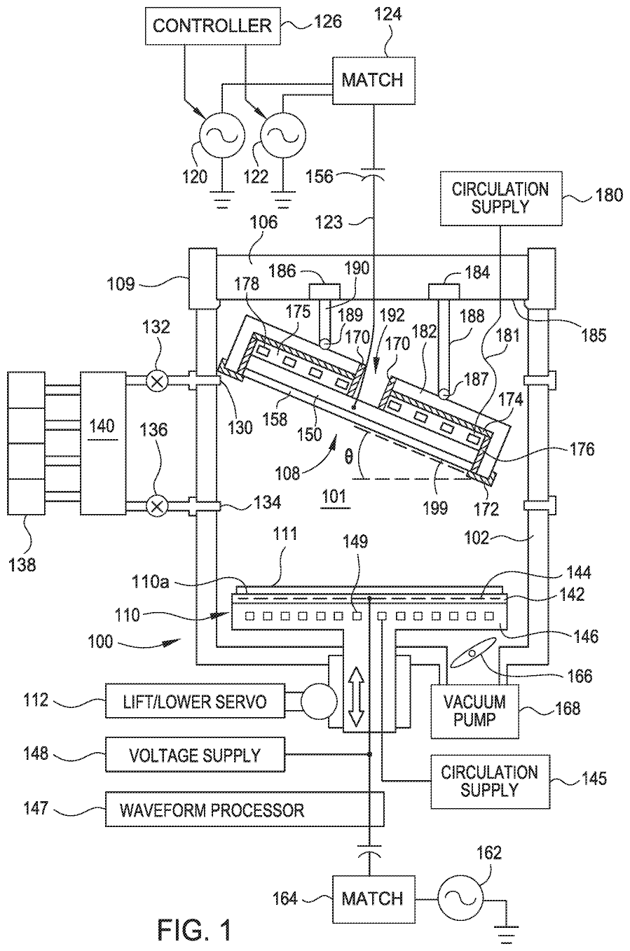

FIG. 1 schematically illustrates an electron beam reactive plasma etching (EBRPE) chamber 100. The chamber 100 has a chamber body 102 which defines a process volume 101. In one embodiment, the chamber body 102 has a substantially cylindrical shape. In other embodiments, the chamber body 102 has a polygonal shape, such as a cubic shape or the like. The chamber body 102 is fabricated from a material suitable for maintaining a vacuum pressure environment therein, such as metallic materials, for example aluminum or stainless steel.

A ceiling 106 is coupled to the chamber body 102 and bounds one side of the process volume 101. In one embodiment, the ceiling 106 is formed from an electrically conductive material, such as the materials utilized to fabricate the chamber body 102. An electrode 108 is coupled to the ceiling 106 and disposed within the process volume 101. A plurality of actuators 184, 186 couple the electrode 108 to the ceiling 106. In one embodiment, the actuators 184, 186 are disposed within recesses formed on a surface 185 of the ceiling 106 which faces and is exposed to the process volume 101. The actuators 184, 186, which may be electrical, pneumatic, mechanical, and/or hydraulic in nature of actuation, are coupled by shafts 188, 190, which extend from respective actuators 184, 186, to the electrode 108. In one embodiment, the actuators 184, 186 are stepper motors.

In one embodiment, the shaft 188 is disposed between the actuator 184 and the electrode 108 and movably couples the electrode 108 to the ceiling 106. Similarly, the shaft 190 is disposed between the actuator 186 and the electrode 108 and movably couples the electrode 108 to the ceiling 106. The actuators 184, 186 separately and independently control the movement of the shafts 188, 190 to enable positioning of the electrode 108 at various angles relative to the ceiling 106. For example, as illustrated in FIG. 1, the shaft 188 extends farther than the shaft 190 from the ceiling 106 to orient the electrode 108 at a non-parallel (i.e., at an angle) relative to the ceiling 106 within the process volume 101. In one embodiment, the shafts 188, 190 are lead screws or ball screws.

Each of the shafts 188, 190 is coupled to the electrode 108 by a respective joint 187, 189. For example, the shaft 188 is coupled to the electrode by the joint 187 and the shaft 190 is coupled to the electrode 108 by the joint 189. The joints 187, 189 are rotational type joints that allow the electrode 108 to move independently of the shafts 188, 190. Examples of suitable joint types include ball and socket joints, pivot joints, hinge joints, saddle joints, universal joints, and the like.

In one embodiment, the electrode 108 is formed from a process-compatible material having a high secondary electron emission coefficient, such as silicon, carbon, silicon carbon materials, or silicon-oxide materials. Alternatively, the electrode 108 is formed from a metal oxide material such as aluminum oxide, yttrium oxide, or zirconium oxide. A dielectric ring 109, which is formed from an electrically insulating material, is coupled to the chamber body 102 and surrounds the ceiling 106, thus electrically isolating the ceiling 106 from the chamber body 102. As illustrated, the dielectric ring 109 is disposed between the chamber body 102 and the ceiling 106 and supports the electrode 108 which extends from the ceiling 106. In one embodiment, the dielectric ring 109 is optional if the electrode 108 is otherwise electrically isolated from the chamber body 102.

A pedestal 110 is disposed in the process volume 101 below the electrode 108. The pedestal 110 supports a substrate 111 thereon during processing and has a substrate support surface 110a oriented parallel to the ceiling 106. In one embodiment, the pedestal 110 is movable in the axial direction by a lift servo 112. The lift servo 112 may optionally rotate the pedestal 110. During operation, the substrate support surface 110a is maintained at a distance of between about 1 inch and about 15 inches from the electrode 108. In one embodiment, the pedestal 110 includes an electrostatic chuck (ESC) 142 which forms the substrate support surface 110a. A conductive mesh 144 is disposed inside the ESC 142, and coupled to a chucking voltage supply 148. Power supplied to the mesh 144 generates an electrostatic force that chucks the substrate 111 to the surface 110a. Additionally, a base layer 146 underlying the ESC 142 has internal passages 149 for circulating a thermal transfer medium (e.g., a gas and/or a liquid) from a circulation supply 145. In one embodiment, the circulation supply 145 includes a heat sink. In another embodiment, the circulation supply 145 includes a heat source. In one embodiment, a temperature of the pedestal 110 is maintained between about −20° C. and about 1000° C.

A first RF power generator 122 having a frequency below the VHF range or below the HF range (e.g., in the MF or LF range, e.g., between about 100 kHz and about 60 MHz, such as about 2 MHz) is coupled to the electrode 108 through an impedance match circuit 124 via an RF feed conductor 123. A second RF power generator 120 having a frequency in the MF or LF range may also be coupled to the electrode 108 through the impedance match circuit 124 via the RF feed conductor 123. In one embodiment, the first RF power generator 122 has a frequency of about 2 MHZ and the second RF power generator 120 has a frequency of about 60 MHz. In one embodiment, the impedance match circuit 124 is adapted to match an impedance of a plasma formed in the process volume 101 at the different frequencies of the RF power generators 120 and 122, as well as filtering to isolate the power generators from one another. Output power levels of the RF power generators 120, 122 are independently controlled by a controller 126. As will be described in detail below, power from the RF power generators 120, 122 is coupled to the electrode 108.

In one embodiment, the ceiling 106 is electrically conductive and is in electrical contact with the electrode 108. Power from the impedance match circuit 124 is conducted through the ceiling 106 to the electrode 108, for example, through the shafts 188, 190 or other conductor. In one embodiment, the chamber body 102 is maintained at ground potential. In one embodiment, grounded internal surfaces (i.e. chamber body 102) inside the chamber 100 are coated with a process compatible material such as silicon, carbon, silicon carbon materials, or silicon-oxide materials. In an alternative embodiment, grounded internal surfaces inside the chamber 100 are coated with a material such as aluminum oxide, yttrium oxide, or zirconium oxide.

With the two RF power generators 120, 122, radial plasma uniformity in the process volume 101 can be controlled by selecting a distance between the electrode 108 and pedestal 110. In this embodiment, the RF power generators 120, 122 produces an edge-high radial distribution of plasma ion density in the process volume 101 and a center-high radial distribution of plasma ion density. With such a selection, the power levels of the two RF power generators 120, 122 are capable of generating a plasma with a substantially uniform radial plasma ion density.

As shown, a cable passage 192 is formed at least partially through the electrode 108 and normal to a bottom surface 199 of the electrode 108. The RF feed conductor 123 and other cables or conductors are disposed through the cable passage 192. A cable insulator 170 in the cable passage 192 if configured to prevent capacitive coupling of the RF feed conductor 123 to a cooling plate 175. In one embodiment, the cable insulator 170 is fabricated from a dielectric material. The cooling plate 175 includes a material suitable for transferring thermal energy, such as metallic materials, for example aluminum or stainless steel.

In one embodiment, the electrode 108 includes an electrode plate 150. A D.C. blocking capacitor 156 is connected in series with the output of the impedance match circuit 124. In one embodiment, the RF feed conductor 123 is directly coupled to the electrode plate 150 through the ceiling 106 and the cable passage 192. In this embodiment, a portion of the RF feed conductor 123 which is disposed in the process volume 101 is flexible in nature to accommodate movement of the electrode 108. In one embodiment, the RF feed conductor 123 from the impedance match circuit 124 is connected to the ceiling 106 rather than being directly connected to the electrode 108. In such an embodiment, RF power from the RF feed conductor 123 is capacitively coupled from the ceiling 106 to the electrode 108.

In one embodiment, the electrode 108 includes an insulating plate 174 formed from an electrically insulating material and coupled to an insulator pipe 176. The insulator pipe 176 may be formed of the same or similar material as the insulating plate 174. The insulating plate 174 and the insulator pipe 176 electrically isolate and prevent capacitive coupling between the electrode plate 150 and the ceiling 106.

In one embodiment, the electrode 108 includes a silicon plate 158 disposed on the electrode plate 150. The silicon plate 158 is positioned by and held adjacent to the electrode plate 150 via an insulator clamp 172. The insulator clamp 172 is fabricated from an electrically insulating material, such as quartz or aluminum oxide. The silicon plate 158 functions to protect a surface 199 of the silicon plate 158 from corrosive species which are generated in the process volume 101 during processing of the substrate 111 or cleaning of the chamber body 102.

In one embodiment, internal passages 178 for conducting a thermally conductive liquid and/or gas inside the cooling plate 175 are connected to a thermal media circulation supply 180. The thermal media circulation supply 180 may also function as a heat sink or a heat source. In one embodiment, the electrode 108 is encased, at least partially, in a protective member 182. The protective member 182 surrounds the electrode 108 such that the surface 199 of the silicon plate 158 is exposed within the process volume 101 and other surfaces of the electrode 108 are covered by the protective member 182. In one embodiment, the protective member 182 is formed from an electrically insulating material, such as quartz or polytetrafluoroethylene. In one embodiment, a grounding material, such as aluminum or the like, is disposed on the protective member 182 when the protective member 182 is formed from an electrically insulating material. In another embodiment, the protective member 182 is fabricated from a metallic material, such as aluminum or stainless steel. The protective member 182 functions to protect various surfaces of the electrode 108 from corrosive species which are generated in the process volume 101 during processing of the substrate 111 or cleaning of the chamber body 102. In the illustrated embodiment, the joints 187, 189 are coupled to the protective member 182, however, it is contemplated that the joints 187, 189 may be coupled to other regions of the electrode 108 depending upon the desired implementation.

In one embodiment, upper gas injectors 130 provide process gas into the process volume 101 through a first valve 132. Lower gas injectors 134 provide process gas into the process volume 101 through a second valve 136. The upper gas injectors 130 and the lower gas injectors 134 are disposed in sidewalls of the chamber body 102. Gas is supplied from a plurality of process gas supplies 138 through a plurality of valves 140 which may include the first and second valves 132 and 136. In one embodiment, the selection of gas species and the rates at which gas is delivered into the process volume 101 are independently controllable. For example, the type and/or rate of gas flowing through the upper gas injectors 130 may be different from the type and/or rate of gas flowing through the lower gas injectors 134. The controller 126 controls the state of the valves 140.

In one embodiment, an inert gas, such as argon or helium, is supplied into the process volume 101 through the upper gas injectors 130 and a process gas is supplied into the process volume 101 through the lower gas injectors 134. In this embodiment, the inert gas delivered to the process volume 101 adjacent the electrode 108 functions to buffer the electrode 108 from a reactive plasma formed in the process volume 101, thus increasing the useful life of the electrode 108. In another embodiment, process gas is supplied to the process volume 101 through both the upper gas injectors 130 and the lower gas injectors 134.

In one embodiment, plasma is generated in the process volume 101 by various bulk and surface processes, for example, by capacitive coupling. In one embodiment, plasma generation is also facilitated by energetic ion bombardment of the surface 199 of the top electron-emitting electrode 108. In one example, the electrode 108 is biased with a substantially negative charge, such as by application of voltage form the voltage supply 154. In one embodiment, bias power applied to the electrode 108 is between about 1 KW and about 10 KW with a frequency of between about 400 kHz and about 200 MHz. It is believed that ions generated by a capacitively coupled plasma are influenced by an electric field that encourages bombardment of the electrode 108 by the ions generated from the plasma.

The ion bombardment energy of the electrode 108 and the plasma density are functions of both RF power generators 120 and 122. The ion bombardment energy of the electrode 108 is substantially controlled by the lower frequency power from the RF power generator 122 and the plasma density in the process volume 101 is substantially controlled (enhanced) by the VHF power from the RF power generator 120. It is believed that ion bombardment of the electrode 108 heats the electrode 108 and causes the electrode 108 to emit secondary electrons. Energetic secondary electrons, which have a negative charge, are emitted from the surface 199 of the electrode 108 and accelerated away from the electrode 108 due to the negative bias of the electrode 108.

The flux of energetic electrons from the surface 199 of the electrode 108 is believed to be an electron beam, and may be oriented substantially perpendicular to the interior surface of the electrode 108. A beam energy of the electron beam is approximately equal to the ion bombardment energy of the electrode 108, which typically can range from about 10 eV to 5000 eV. In one embodiment, the plasma potential is greater than the potential of the electrode 108 and the energetic secondary electrons emitted from the electrode 108 are further accelerated by a sheath voltage of the plasma as the secondary electrons traverse through the plasma.

At least a portion of the electron beam, comprised of the secondary electron flux emitted from electrode 108 due to energetic ion bombardment of the electrode surface 199, propagates through the process volume 101 and reacts with process gases near the substrate 111. With utilization of suitable process gases, such as chlorine containing materials, fluorine containing materials, bromine containing materials, oxygen containing materials, and the like, the electron beam induces etching reactions on the substrate 111. It is believed that the electron beams, in addition to the capacitively generated plasma, generate chemically reactive radicals and ions which adsorb to the surface of the substrate and form a chemically reactive polymer layer on the surface of the substrate 111.

In one embodiment, an RF bias power generator 162 is coupled through an impedance match 164 to the conductive mesh 144 or other electrode of the pedestal 110. In a further embodiment, a waveform tailoring processor 147 may be connected between the output of the impedance match 164 and the conductive mesh 144. The waveform tailoring processor 147 changes the waveform produced by the RF bias power generator 162 to a desired waveform. The ion energy of plasma near the substrate 111 is controlled by the waveform tailoring processor 147. In one embodiment, the waveform tailoring processor 147 produces a waveform in which the amplitude is held during a certain portion of each RF cycle at a level corresponding to a desired ion energy level. The controller 126 controls the waveform tailoring processor 147.

Accordingly, the electron beam induces chemical reactions to liberate gas phase volatile products and etch the substrate 111. Etching of the substrate 111 is also influenced by other factors, such as pressure. In one embodiment, a vacuum maintained in the process volume 101 during electron beam etching of the substrate 111 is between about 0.1 Torr and about 10 Torr. The vacuum is generated by a vacuum pump 168 which is in fluid communication with the process volume 101. The pressure within the process volume 101 is regulated by a throttle valve 166 which is disposed between the process volume 101 and the vacuum pump 168.

Other factors which influence etching characteristics of the substrate 111 include the angle θ at which the surface 199 of the electrode 108 is disposed relative to the substantially horizontal orientation of the surface 110a of pedestal 110 and the substrate 111 disposed thereon. In one embodiment, the angle θ is between about 1° and about 45°, such as between about 5° and about 30°, for example, between about 10° and about 20°. As a result of the tilting of the electrode 108 to an orientation that is non-parallel to the ceiling 106 and surface 110a of the pedestal 110, secondary electrons contact the substrate 111 at substantially non-perpendicular angles which enable the substrate 111 to be etched with slanted features. Slanted etching is believed to enable advanced feature formation and can advantageously be implemented in the formation of various optical devices and the like.

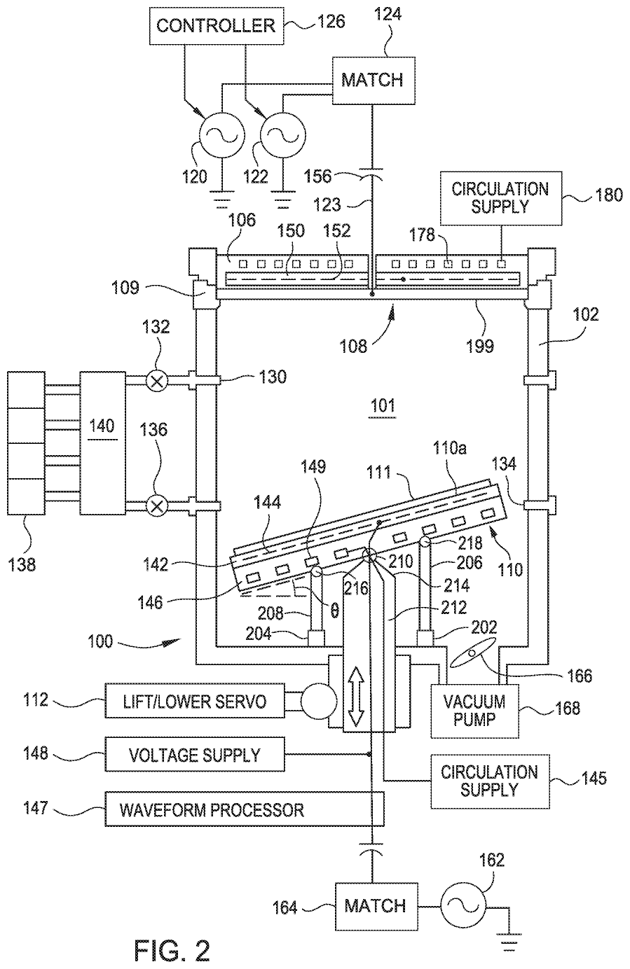

FIG. 2 schematically illustrates another embodiment of the EBRPE apparatus 100. In the illustrated embodiment, the electrode 108 and the ceiling 106 are maintained in a parallel and substantially horizontal position. The support surface 110a of the pedestal 110 is capable of being positioned in a non-horizontal orientation relative to a substantially horizontal orientation of the electrode 108. In other words, the pedestal 110 is movable such that the surface 110a of the pedestal 110 can be positioned in a non-parallel orientation relative to the surface 199 of the electrode 108. Aspects of the embodiment illustrated in FIG. 2 which are common to the embodiment of FIG. 1 are described above.

The ceiling 106 is coupled to and supports the electrode 108 within the process volume 101. In one embodiment, the electrode 108 is coupled by mechanical clamping to the ceiling 106 such that the surface 199 of the electrode 108 is exposed to the process volume 101 and faces the support surface 110a of the pedestal 110. In this embodiment, the ceiling 106 is a support for the electrode 108 which includes an insulating layer 150 containing a conductive mesh 152 facing the surface 199. A D.C. blocking capacitor 156 is connected in series with the output of the impedance match circuit 124. In one embodiment, the RF feed conductor 123 form the impedance match circuit is connected to the conductive mesh 152. In another embodiment, the RF feed conductor 123 from the impedance match circuit 124 is connected to the electrode support or ceiling 106 rather than being directly connected to the electrode 108. In such an embodiment, RF power from the RF feed conductor 123 is capacitively coupled from the electrode support to the electrode 108.

In one embodiment, internal passages 178 for conducting a thermally conductive liquid and/or gas inside the ceiling 106 are connected to a thermal media circulation supply 180. The thermal media circulation supply 180 acts as a heat sink or a heat source. The mechanical contact between the electrode 108 and the ceiling 106 is sufficient to maintain high thermal conductance between the electrode 108 and the ceiling 106.

The pedestal 110 is coupled to a support shaft 212 by a joint 210. The joint 210 rotatably couples the pedestal to the support shaft 212 to enable movement of the pedestal 110 between one or more angles θ. The joint 210 is disposed between the base layer 146 of the pedestal 110 and a topmost portion of the support shaft 212. Examples of suitable joint types for the joint 210 include ball and socket joints, pivot joints, hinge joints, saddle joints, universal joints, and the like. A topmost portion of the support shaft 212 has a tapered surface 214. The tapered surface 214 extends from the joint 210 with an increasing radius down the support shaft 212. As such, a radius of the support shaft 212 at the joint 210 is less than the radius of the support shaft 212 elsewhere along a length of the support shaft 212. Thus, the tapered surface 214 enables the pedestal 110 to be positioned at various angle magnitudes without interference from the support shaft 212. It is also contemplated that conduits extending from one or more of the voltage supply 148, the impedance match 164, and the circulation supply 145 extend through the support shaft 212 and the joint 210 to the pedestal 110.

In one embodiment, a plurality of actuators 202, 204 are coupled to the chamber body 102 in the process volume 101. In another embodiment, the plurality of actuators 202, 204 are disposed outside of the process volume 101. The actuators 202, 204 which may be electrical, pneumatic, mechanical, and/or hydraulic in nature of actuation, are coupled to shafts 206, 208 which extend from respective actuators 202, 204 to the pedestal 110. In one embodiment, the actuators 202, 204 are linear motors or stepper motors. In one embodiment, the shafts 206, 208 are leads screws or ball screws. In embodiments where the actuators 202, 204 are disposed outside of the process volume 101, the shafts 206, 208 are configured to extend from the actuators 202, 204 through the chamber body 102 to the pedestal 110. In this embodiment, sealing apparatus may be disposed at regions of the chamber body 102 where the shafts 206, 208 extend through the chamber body 102.

In one embodiment, the shaft 206 is disposed between the actuator 202 and the pedestal 110 and movably actuates the pedestal 110 about the support shaft 212. Similarly, the shaft 208 is disposed between the actuator 204 and the pedestal and movably actuates the pedestal 110 about the support shaft 212. The shafts 206, 208 may be telescopic to enable different magnitudes of travel to facilitate an angled positioning of the pedestal. For example, as illustrated in FIG. 2, the shaft 206 is extended to a greater degree than the shaft 208 to orient the surface 110a of the pedestal 110 at a non-zero angle relative to the surface 199 of the electrode 108 within the process volume 101.

Each of the shafts 206, 208 is coupled to the pedestal 110 by a respective joint 218, 216. For example, the shaft 206 is coupled to the pedestal 110 by the joint 218 and the shaft 208 is coupled to the pedestal 110 by the joint 216. The joints 216, 218 are rotational type joints that allow the pedestal 110 to move independently of the shafts 206, 208. Examples of suitable joint types for the joints 216, 218 include ball and socket joints, pivot joints, hinge joints, saddle joints, universal joints, and the like.

The ability to angle the surface 110a of the pedestal 110 with respect to the surface 199 of the electrode 108 provides for the ability to perform slanted etching on the substrate 111. The angle θ at which the surface 110a of the pedestal 110 is disposed relative to the substantially horizontal orientation of the surface 199 of the electrode 108 influences etching characteristics of the substrate 111, among other factors. In one embodiment, the angle θ is between about 1° and about 45°, such as between about 5° and about 30°, for example, between about 10° and about 20°. As a result of the angled disposition of the pedestal 110, secondary electrons contact the substrate 111 at substantially non-perpendicular angles which enable the substrate 111 to be etched with slanted features. Slanted etching is believed to enable advanced feature formation and can advantageously be implemented in the formation of various optical devices and the like.

In operation, the pedestal 110 is positioned in a substantially horizontal orientation during placement of the substrate 111 on the pedestal 110. After the substrate 111 is secured to the pedestal 110, the surface 110a of the pedestal 110 is tilted to the desired angle θ by extension of the shafts 206, 208 by the actuators 202, 204. An EBRPE process is performed while the pedestal 110 is in the tilted orientation and the pedestal 110 is returned to a substantially horizontal orientation after EBRPE processing has stopped.

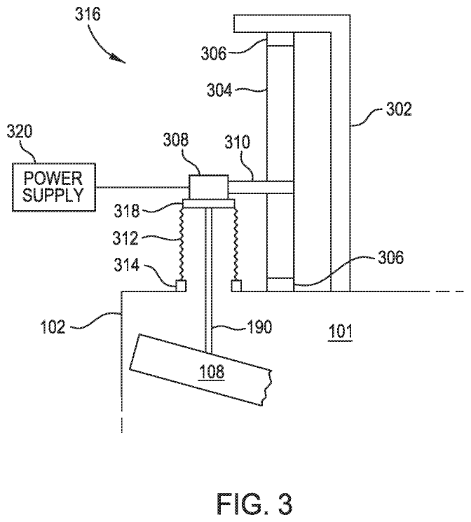

FIG. 3 illustrates an actuator assembly 316 of the EBRPE apparatus 100 according to an embodiment described herein. The actuator assembly 316 is configured to extend or retract either of the shafts 188, 190 into the process volume 101. The actuator assembly 316 includes a shaft 304, a link 310, and a motor 308. The motor 308 is disposed on a motor base plate 318 and supported by the link 310. A power supply 320 supplies electrical power to the motor 318.

A brace 302 is coupled to the chamber body 102 and supports the actuator assembly 316. A first end of the shaft 304 is coupled to the brace 302 via a connector 306. A second end of the shaft 304 opposite the first end is coupled to the chamber body 102 via the connector 306. The link 310 is moveably coupled to the shaft 304. For example, the shaft 304 and link 310 may comprise a ball screw and ball nut, respectively.

The link 310 is configured to transfer linear or rotational energy from the motor 308 to the shaft 304. In one embodiment, the shaft 304 is stationary and the motor 308 is configured to move the link 310 along the shaft 304. In another embodiment, the motor 308 may be disposed on the brace 302 and configured to move the shaft 304 with a link 310 that is fixably coupled to the motor base plate 318.

The actuator assembly 316 is fluidly sealed from the process volume 101 by bellows 312 and an seal 314. The shaft 190 moveably couples the electrode 108 to the motor base plate 318. FIG. 3 depicts a portion of the chamber body 102 and the electrode 108. While a single actuator assembly 316 is shown in FIG. 3, it is contemplated that one or more additional actuator assemblies may couple the electrode 108 to the chamber body 102.

By utilizing electron beams generated in accordance with the embodiments described above, reactive species which are not readily obtained with conventional etching processes may be generated. For example, reactive species with high ionization and/or excitation/dissociation energies may be obtained with the EBRPE methods and apparatus described herein. It is also believed that the EBRPE methods described herein provide for etching rates equivalent to or greater than conventional etching processes, but with improved material selectivity.

For example, EBRPE methods are believed to provide improved etch selectivity due to the separation of threshold electron beam energies used to induce etching reactions. For example, with certain polymerizing gas chemistries, the threshold energy utilized to etch silicon oxide materials is much greater than the threshold energy utilized to etch silicon. As a result, it is possible to achieve etch selectivities of about 5:1 or greater. In one embodiment, EBRPE is believed to enable about 5:1 silicon:silicon oxide etch selectivity. In another embodiment, EBRPE is believed to enable about 5:1 tungsten:silicon nitride etch selectivity.

The kinetic energy of electrons is also much less than that of ions. As a result, substrate damage is reduced because the potential for sputtering is reduced. Moreover, by controlling the electron beam energy, such as by application of RF power to the electrode, EBRPE is believed to provide a “softer” etch than conventional etching processes. With improved control, EBRPE is able to produce tapered etch profiles, such as etching profiles utilized in certain shallow trench isolation applications. Moreover, by enabling slant etching by either tilt positioning of the electrode or the pedestal, advanced etching profiles and operations may be performed.

While the foregoing is directed to embodiments of the present disclosure, other and further embodiments of the disclosure may be devised without departing from the basic scope thereof, and the scope thereof is determined by the claims that follow.

What is claimed is:

1. A substrate processing apparatus, comprising:
a chamber body defining a volume;
a pedestal disposed in the volume;
a ceiling coupled to the chamber body and opposite the pedestal; and
an electrode disposed in the volume between the pedestal and the ceiling, at least one of the electrode or pedestal movable to orient a surface of the electrode facing a surface of the pedestal in a non-parallel orientation.

2. The apparatus of claim 1, wherein a plurality of actuators are disposed in the ceiling and operable to control an angular orientation of the electrode.

3. The apparatus of claim 2, wherein a plurality of shafts couple the electrode to the plurality of actuators.

4. The apparatus of claim 3, wherein the plurality of shafts are coupled to the electrode by a plurality of joints.

5. The apparatus of claim 3, wherein the electrode includes a cable passage surrounded by a cable insulator.

6. The apparatus of claim 1, wherein the surface of the electrode facing the pedestal is coupled to a plate.

7. The apparatus of claim 6, wherein the plate comprises a silicon containing material.

8. The apparatus of claim 7, wherein the electrode is surrounded by a protective member such that the plate is exposed to the volume.

9. The apparatus of claim 8, wherein protective member comprises aluminum.

10. The apparatus of claim 1, further comprising:
a first gas injector fluidly coupled to the volume through the chamber body adjacent the electrode; and
a second gas injector fluidly coupled to the volume through the chamber body adjacent the pedestal.

11. A substrate processing apparatus, comprising:
a chamber body defining a volume;
a ceiling coupled to the chamber body;
an electrode coupled to the ceiling;
a pedestal disposed in the volume and having a surface facing a surface of the electrode; and
an actuator coupled to the pedestal and configured to position a surface of the pedestal facing the surface of the electrode in a non-parallel orientation relative to a surface of the electrode.

12. The apparatus of claim 11, further comprising:
a support shaft having a tapered surface at the electrode.

13. The apparatus of claim 11, further comprising:
a plurality of actuators;
a plurality of shafts extending from the plurality of actuators; and
a plurality of joints coupled between the plurality of shafts and the pedestal.

14. The apparatus of claim 13, wherein the actuators are electrical actuators, pneumatic, mechanical actuators, or hydraulic actuators.

15. The apparatus of claim 13, wherein the plurality of joints are ball and socket joints, pivot joints, hinge joints, saddle joints, or universal joints.

16. The apparatus of claim 11, wherein the electrode is electrostatically chucked to the ceiling.

17. The apparatus of claim 11, wherein the pedestal further comprises an electrostatic chuck.

18. The apparatus of claim 17, wherein one or more fluid channels are disposed in a base layer coupled to the electrostatic chuck.

19. The apparatus of claim 11, further comprising:
a first gas injector fluidly coupled to the volume through the chamber body adjacent the electrode; and
a second gas injector fluidly coupled to the volume through the chamber body adjacent the pedestal.

20. A substrate processing apparatus, comprising:
a chamber body defining a volume;
an electrode for performing electron beam reactive plasma etching disposed in the volume;
a pedestal coupled to a support shaft, the pedestal disposed in the volume opposite the electrode;
a conductive mesh disposed in the pedestal;
a plurality of shafts coupled to either the electrode or the pedestal;
a one or more ball screw actuators coupled to the shafts;
a first gas injector coupled to the chamber body adjacent the electrode; and
a second gas injector coupled to the chamber body adjacent the pedestal.
